(19) United States
(12) Patent Application Publication
(10) Pub. No.: US 2025/0046670 A1
(43) Pub. Date: Feb. 6, 2025

(54) ELECTRONIC PACKAGE AND HEAT DISSIPATION STRUCTURE THEREOF

(71) Applicant: SILICONWARE PRECISION INDUSTRIES CO., LTD., Taichung City (TW)

(72) Inventors: Wei-Jhen CHEN, Taichung City (TW); Chih-Hsun HSU, Taichung City (TW); Chih-Nan LIN, Taichung City (TW); Yuan-Hung HSU, Taichung City (TW); Don-Son JIANG, Taichung City (TW)

(21) Appl. No.: 18/479,892

(22) Filed: Oct. 3, 2023

(30) Foreign Application Priority Data
Jul. 31, 2023 (TW) 112128663

(51) Int. Cl. H01L 23/367; H01L 23/00

(52) U.S. Cl. CPC H01L 23/3675; H01L 24/16; H01L 24/32; H01L 24/73; H01L 23/49816; H01L 2224/16225; H01L 2224/32225; H01L 2224/32245; H01L 2224/73204; H01L 2224/73253; H01L 2924/1711; H01L 2924/172; H01L 2924/35121

(57) ABSTRACT

An electronic package and a heat dissipation structure thereof are provided, in which supporting members of the heat dissipation structure are arranged in edge areas, and no supporting member is arranged in corner areas. In this way, the supporting members are interrupted at the corner areas, so that stress can be prevented from concentrating in the corner areas, and the entire electronic package can be prevented from warping and delamination.

### BACKGROUND

### 1. Technical Field

The present disclosure relates to a package structure, and more particularly, to an electronic package for improving reliability and a heat dissipation structure thereof.

### 2. Description of Related Art

With the improvement of electronic products in terms of function and processing speed, semiconductor chips as the core components of electronic products need to have higher density electronic components and electronic circuits. Accordingly, the semiconductor chip will generate a greater amount of heat energy during operation, and the encapsulant covering the semiconductor chip is made of a material with poor thermal conductivity (that is, the heat dissipation efficiency is not good). Therefore, if the heat generated cannot be effectively dissipated, it will cause damage to the semiconductor chip or cause product reliability problems.

Therefore, in order to quickly dissipate heat energy into the atmosphere, a heat dissipation sheet (heat sink or heat spreader) is usually arranged in the semiconductor package structure to dissipate the heat generated by the semiconductor chip via the heat dissipation sheet. Furthermore, it is generally that the top surface of the heat dissipation sheet is exposed from the encapsulant or is directly exposed to the atmosphere, so as to obtain a better heat dissipation effect.

As shown in FIG. 1, in the method of manufacturing a conventional heat-dissipating semiconductor package structure 1, a semiconductor chip 11 is first provided on a package substrate 10 with an active surface 11a thereof by means of flip-chip bonding (that is, via conductive bumps 110 and an underfill 111), and a gold layer (not shown) is formed on an inactive surface 11b of the semiconductor chip 11, and then a heat dissipation member 13 is bonded onto the gold layer with a top sheet 130 thereof via a TIM (thermal interface material) layer 12 (which includes a solder layer and flux) by reflow soldering, and supporting legs 131 of the heat dissipation member 13 are erected on the package substrate 10 via an adhesive layer 14. Next, the encapsulation molding operation is carried out, so that the encapsulant (not shown) covers the semiconductor chip 11 and the heat dissipation member 13, and the top sheet 130 of the heat dissipation member 13 is exposed from the encapsulant and directly contacts with the atmosphere.

During operation, the heat energy generated by the semiconductor chip 11 is conducted to the heat dissipation member 13 via the inactive surface 11b and the TIM layer 12 to dissipate heat to the outside of the semiconductor package structure 1.

However, when the thickness of the conventional semiconductor package structure 1 becomes thinner and its area becomes larger and larger, the deformation (that is, the extent of warpage) caused by the CTE (coefficient of thermal expansion) mismatch between the heat dissipation member 13 and the TIM layer 12 becomes more apparent. Especially the corners of the semiconductor package structure 1 will bear the maximum stress, so that delamination (a gap d as shown in FIG. 1) will easily occur between the top sheet 130 of the heat dissipation member 13 and the TIM layer 12. Therefore, not only the heat conduction effect is reduced, but also the appearance of the semiconductor package structure 1 is poor, thereby seriously affecting the reliability of the product.

Therefore, how to overcome the above-mentioned drawbacks of the prior art has become an urgent issue to be solved at present.

### SUMMARY

In view of the various deficiencies of the prior art, the present disclosure provides a heat dissipation structure, which comprises: a heat dissipation member defined with a central area, a plurality of edge areas located at sides of an outer periphery of the central area, and a plurality of corner areas located at corners of the outer periphery of the central area; and at least one supporting member disposed on the heat dissipation member; wherein the supporting member is disposed in the edge area of the heat dissipation member and is not disposed in the corner area.

The present disclosure also provides an electronic package, which comprises: a carrier structure; an electronic component disposed on the carrier structure; and a heat dissipation structure disposed on the carrier structure and covering the electronic component, and the heat dissipation structure comprising: a heat dissipation member defined with a central area, a plurality of edge areas located at sides of an outer periphery of the central area, and a plurality of corner areas located at corners of the outer periphery of the central area; and at least one supporting member disposed on the heat dissipation member, wherein the heat dissipation structure is disposed on the carrier structure via the supporting member; wherein the electronic component is corresponding to a position of the central area, and the supporting member is disposed in the edge area of the heat dissipation member but not in the corner area.

In the aforementioned electronic package and heat dissipation structure, the present disclosure further comprises at least one joint member disposed in the corner area of the heat dissipation member, wherein the joint member and the supporting member are not connected to each other. Alternatively, in the aforementioned electronic package and heat dissipation structure, the present disclosure further comprises a plurality of joint members disposed in some of the plurality of corner areas, for example, the plurality of joint members are disposed in the plurality of corner areas that are opposite.

In the aforementioned electronic package and heat dissipation structure, the joint member is made of soft material, and the supporting member is made of hard material.

In the aforementioned electronic package and heat dissipation structure, the joint member is a glue pillar.

In the aforementioned electronic package and heat dissipation structure, the supporting member is a heat dissipation wall or a heat dissipation pillar.

In the aforementioned electronic package and heat dissipation structure, a plurality of the supporting members are disposed in one of the edge areas and spaced apart from each other.

In the aforementioned electronic package and heat dissipation structure, the supporting member is disposed in each of two of the edge areas that are opposite.

In the aforementioned electronic package and heat dissipation structure, the supporting member is disposed in each of the edge areas.

In the aforementioned electronic package and heat dissipation structure, the heat dissipation member and the supporting member are integrally formed.

In the aforementioned electronic package and heat dissipation structure, the heat dissipation member and the supporting member are not integrally formed.

As can be seen from the above, in the electronic package and the heat dissipation structure thereof of the present disclosure, the supporting members of the heat dissipation structure are mainly provided in the edge areas, and no supporting members are provided in the corner areas. Thereby, the supporting members located in the edge areas are interrupted at the corner areas and are not connected to each other. Therefore, compared with the prior art in which the supporting legs surround the entire outer periphery of the top sheet of the heat dissipation member, the stress of the supporting members of the present disclosure will not be concentrated in the corner areas, thereby preventing the entire electronic package from warping and delamination.

Moreover, the heat dissipation structure of the present disclosure can be provided with the joint member in the corner area, and the joint member can strengthen the connection between the heat dissipation member and the carrier structure. Therefore, the stability of the entire electronic package can be further improved by the joint member to avoid bending deformation.

### BRIEF DESCRIPTION OF THE DRAWINGS

FIG. 1 is a schematic cross-sectional view of a conventional semiconductor package structure.

FIG. 2A to FIG. 2F are schematic cross-sectional views illustrating a manufacturing method of an electronic package according to the present disclosure.

FIG. 3A is a three-dimensional schematic view of a heat dissipation structure according to a first embodiment of the present disclosure.

FIG. 3B is a schematic plan view of the heat dissipation structure according to the first embodiment of the present disclosure.

FIG. 4A is a three-dimensional schematic view of a heat dissipation structure according to a second embodiment of the present disclosure.

FIG. 4B is a schematic plan view of the heat dissipation structure according to the second embodiment of the present disclosure.

FIG. 5A is a three-dimensional schematic view of a heat dissipation structure according to a third embodiment of the present disclosure.

FIG. 5B is a schematic plan view of the heat dissipation structure according to the third embodiment of the present disclosure.

FIG. 6A is a three-dimensional schematic view of a heat dissipation structure according to a fourth embodiment of the present disclosure.

FIG. 6B is a schematic plan view of the heat dissipation structure according to the fourth embodiment of the present disclosure.

FIG. 7A is a three-dimensional schematic view of a heat dissipation structure according to a fifth embodiment of the present disclosure.

FIG. 7B is a schematic plan view of the heat dissipation structure according to the fifth embodiment of the present disclosure.

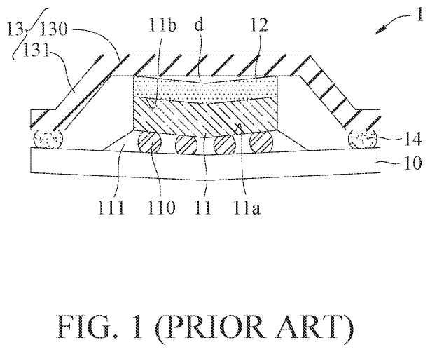

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “below,” “first,” “second,” “a,” “one” and the like are merely used for clear explanation rather than limiting the practicable scope of the present disclosure, and thus, alterations or adjustments of the relative relationships thereof without essentially altering the technical contents should still be considered in the practicable scope of the present disclosure.

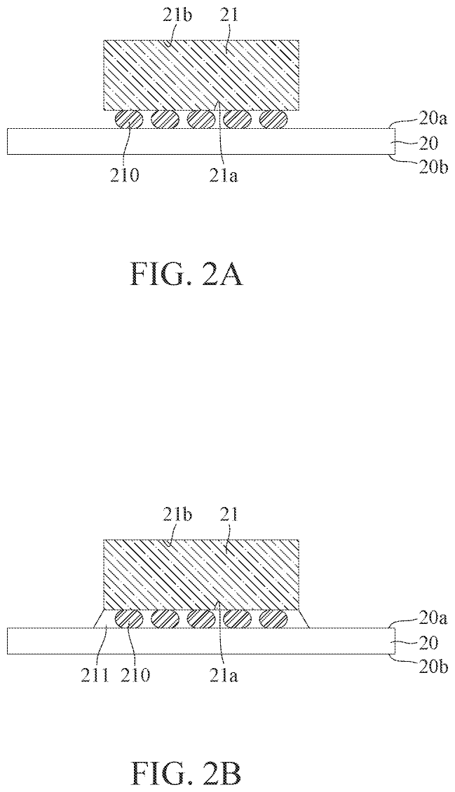

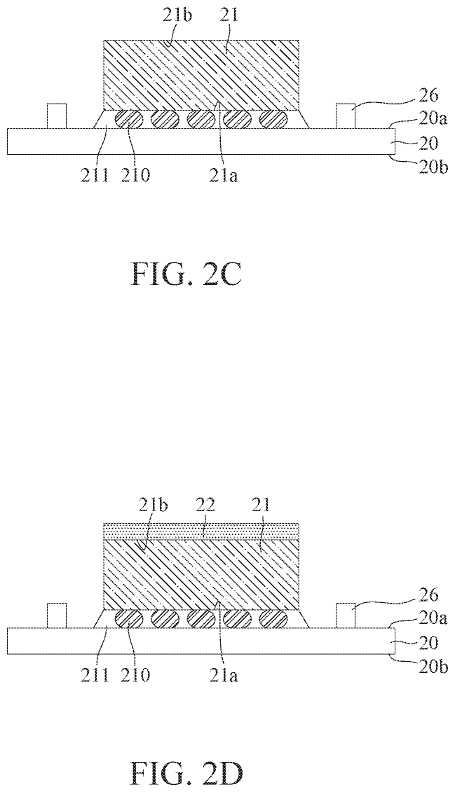

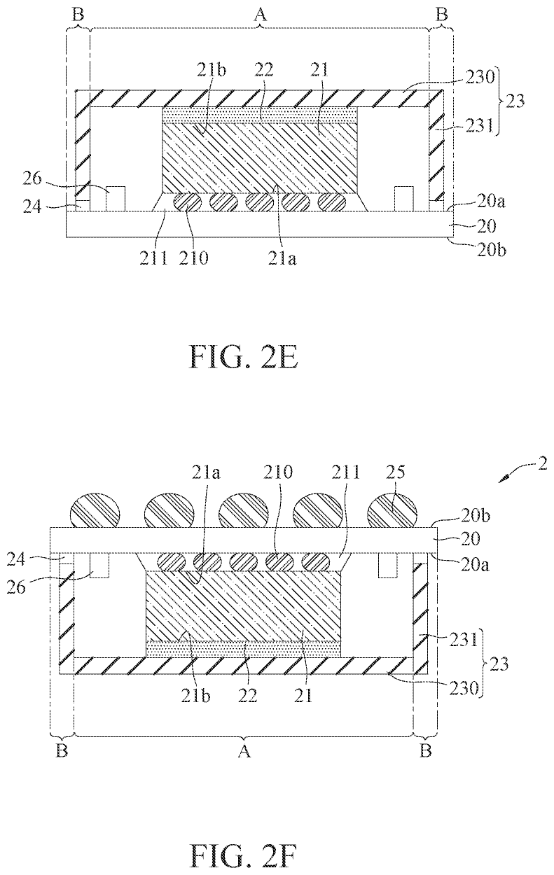

FIG. 2A to FIG. 2F are schematic cross-sectional views illustrating a manufacturing method of an electronic package 2 according to the present disclosure.

As shown in FIG. 2A, a carrier structure 20 is provided and has a first side 20a and a second side 20b opposing the first side 20a, and at least one electronic component 21 is disposed on the first side 20a of the carrier structure 20.

The carrier structure 20 may be a package substrate (substrate) with a core layer and a circuit portion or a circuit structure without a core layer (coreless).

In one embodiment, the carrier structure 20 includes at least one dielectric layer and a circuit layer bonded to the dielectric layer, such as of a fan-out type redistribution layer (RDL) specification. For example, the first side 20a of the carrier structure 20 is used as a die placement side for carrying the electronic component 21, and the second side 20b of the carrier structure 20 is used as a ball placement side.

It should be understood that the carrier structure 20 may also be other types of carrier unit for carrying a chip, such as a lead frame, a wafer, a silicon interposer, or other types of board having metal routings, and the like, and the present disclosure is not limited to as such.

The electronic component 21 is an active component, a passive component, or a combination of the active component and the passive component, wherein the active component is such as a semiconductor chip, and the passive component is such as a resistor, a capacitor, or an inductor.

In one embodiment, the electronic component 21 is a semiconductor chip and has an active surface 21a and an inactive surface 21b opposing the active surface 21a, and a plurality of electrode pads (not shown) are formed on the active surface 21a, so that the electrode pads are flip-chip bonded to and electrically connected to the circuit layer of the carrier structure 20 via a plurality of conductive bumps 210 made of solder material.

In other embodiments, the electronic component 21 can also be electrically connected to the circuit layer of the carrier structure 20 via a plurality of bonding wires; or, the electronic component 21 can directly contact the circuit layer of the carrier structure 20.

It should be understood that there are many ways to electrically connect the electronic component 21 to the carrier structure 20, and the required types and quantities of the electronic components 21 can be placed on the carrier structure 20, and the present disclosure is not limited to as such.

As shown in FIG. 2B, a cladding layer such as an underfill 211 is filled and formed between the first side 20a of the carrier structure 20 and the active surface 21a of the electronic component 21 to cover the conductive bumps 210.

As shown in FIG. 2C, at least one passive component 26 is disposed on the carrier structure 20, so that the passive component 26 is electrically connected to the circuit layer.

As shown in FIG. 2D, a heat conduction layer 22 is formed on the inactive surface 21b of the electronic component 21.

In an embodiment, the heat conduction layer 22 is used as a thermal interface material (TIM). For example, the heat conduction layer 22 can be liquid metal such as solder material and has high thermal conductivity.

As shown in FIG. 2E, a heat dissipation structure 23 is disposed on the first side 20a of the carrier structure 20 and the heat conduction layer 22 to cover the electronic component 21. The heat dissipation structure 23 has a heat dissipation member 230 that is in contact with and bonded to the heat conduction layer 22, and the heat dissipation structure 23 has a plurality of supporting members 231 extending downward from the heat dissipation member 230 and bonded to the carrier structure 20. For example, the heat dissipation member 230 is of a sheet type and can be pressed against the heat conduction layer 22, so that the heat conduction layer 22 is located between the heat dissipation member 230 and the electronic component 21.

Moreover, the supporting members 231 are bonded onto the carrier structure 20 via an adhesive layer 24. For example, the adhesive layer 24 is first formed on the first side 20a of the carrier structure 20 by dispensing glue, so that the adhesive layer 24 is located at the periphery of the passive component 26, and then the supporting members 231 are bonded onto the adhesive layer 24 to fix the heat dissipation structure 23 on the carrier structure 20.

Afterward, as shown in FIG. 2F, an encapsulant (not shown) covering the electronic component 21 can be formed on the first side 20a of the carrier structure 20, and a plurality of conductive components 25, such as metal pillars of copper pillars, metal bumps covered with insulating blocks, solder balls, solder balls with copper core balls or other conductive structures, are disposed on the second side 20b of the carrier structure 20, so as to manufacture and obtain the electronic package 2 of the present disclosure. Subsequently, the electronic package 2 can be connected to an electronic device (not shown) such as a circuit board via the conductive components 25.

When the electronic package 2 is in operation, the heat energy generated by the electronic component 21 is conducted to the heat dissipation structure 23 via the inactive surface 21b and the heat conduction layer 22, so as to dissipate heat to the outside of the electronic package 2.

Hereinafter, various implementations of the heat dissipation structure 23 of the aforementioned electronic package 2 of the present disclosure will be described in more detail.

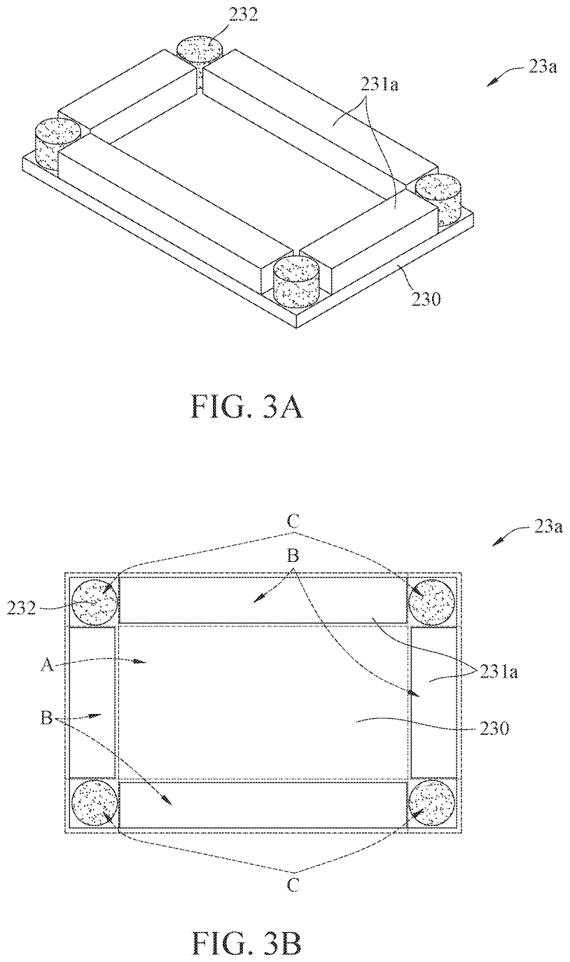

FIG. 3A and FIG. 3B show a heat dissipation structure 23a according to a first embodiment of the present disclosure. As shown in FIG. 3B, the heat dissipation member 230 of the heat dissipation structure 23a is defined with a central area A, a plurality of edge areas B located at the sides of the outer periphery of the central area A, and a plurality of corner areas C located at the corners of the outer periphery of the central area A. For example, in an embodiment, the heat dissipation member 230 is defined with one central area A, four edge areas B and four corner areas C.

In one embodiment, the central area A corresponds to the area where the electronic component 21 and the passive component 26 are disposed (as shown in FIG. 2E and FIG. 2F). Moreover, as shown in FIG. 3A and FIG. 3B, a single supporting member 231a is provided in each of the edge areas B, and the supporting member 231a is not provided in the corner area C. In other words, the plurality of supporting members 231a located in the plurality of edge areas B are interrupted at the corner area C and are not connected to each other. In addition, a joint member 232 is disposed in each of the corner areas C, and the joint member 232 and the supporting member 231 are not connected to each other.

Accordingly, the stress of the heat dissipation structure 23a will not be concentrated at the corner areas C, thereby preventing the entire structure from warping and delamination. Furthermore, the joint member 232 can strengthen the connection between the heat dissipation member 230 and the carrier structure 20. Therefore, the stability of the entire structure can be further improved to avoid bending deformation.

The material of the supporting member 231a can be the same as the material of the heat dissipation member 230, for example, a heat dissipation wall or a heat dissipation pillar made of a hard material (metal). Thereby, the heat dissipation effect of the entire heat dissipation structure 23a can be improved. However, it should be understood that the supporting member 231a can also be other members capable of supporting the heat dissipation member 230, and the present disclosure is not limited to as such.

Furthermore, in one embodiment, the supporting member 231a is disposed in each of the edge areas B. However, it should be understood that the supporting member 231a only needs to be sufficient to support the heat dissipation member 230, and the supporting member 231a may not be provided in each of the edge areas B.

The joint member 232 may be made of elastic soft material (adhesive glue), such as a glue pillar. Thereby, the toughness of the entire heat dissipation structure 23a can be improved. However, it should be understood that the joint member 232 can also be other members capable of connecting the heat dissipation member 230 and the carrier structure 20, and the present disclosure is not limited to as such.

Furthermore, in one embodiment, the joint member 232 is disposed in each of the corner areas C. However, it should be understood that the joint member 232 only needs to be sufficient to connect the heat dissipation member 230 to the carrier structure 20, and the joint member 232 may not be provided in each of the corner areas C.

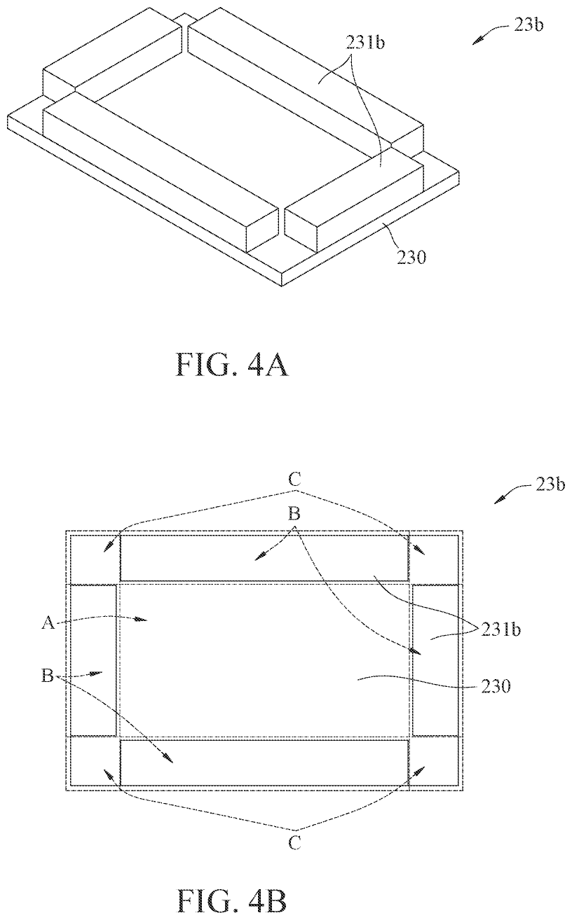

FIG. 4A and FIG. 4B show a heat dissipation structure 23b according to a second embodiment of the present disclosure. The same or corresponding members of the heat dissipation structure 23b of the second embodiment and the heat dissipation structure 23a of the first embodiment are marked with the same or corresponding numbers, and descriptions of the same parts are omitted.

As shown in FIG. 4A and FIG. 4B, in the second embodiment of the present disclosure, the above-mentioned joint member 232 is not provided in the corner area C. In other words, only supporting members 231b located in the edge areas B are supported and connected between the heat dissipation member 230 and the carrier structure 20.

Compared with the first embodiment, the structure of the heat dissipation structure 23b of the second embodiment is simpler, so the manufacturing process of the heat dissipation structure 23b can be simplified and the cost can be reduced. In addition, if encapsulation process is performed later, the encapsulant can be filled from the corner areas C to cover the electronic component 21, and at the same time, air bubbles in the encapsulation process can also be discharged from the corner areas C.

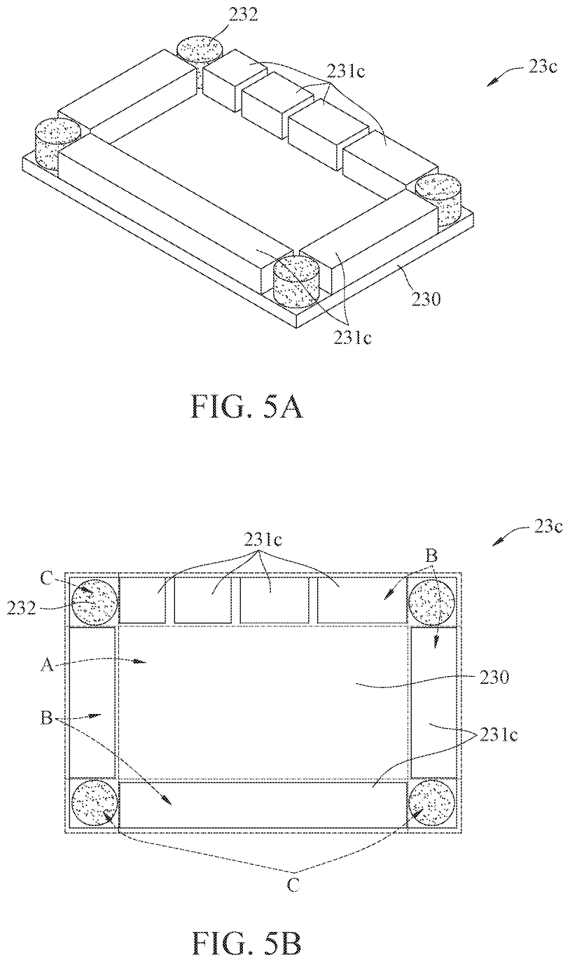

FIG. 5A and FIG. 5B show a heat dissipation structure 23c according to a third embodiment of the present disclosure. The same or corresponding members of the heat dissipation structure 23c of the third embodiment and the heat dissipation structure 23a of the first embodiment are marked with the same or corresponding numbers, and descriptions of the same parts are omitted.

As shown in FIG. 5A and FIG. 5B, in the third embodiment of the present disclosure, a plurality of supporting members 231c are provided in at least one of the edge areas B, and the plurality of supporting members 231c are arranged to be spaced apart from each other. Furthermore, the dimensions of the plurality of supporting members 231c can be the same or different.

Compared with the first embodiment, the heat dissipation structure 23c of the third embodiment is provided with a plurality of supporting members 231c on a single side, and the remaining three sides are provided with a single supporting member 231c, respectively. Therefore, the stress in the edge area B of the single side can be interrupted, thereby improving the stability of the entire structure and avoiding bending deformation.

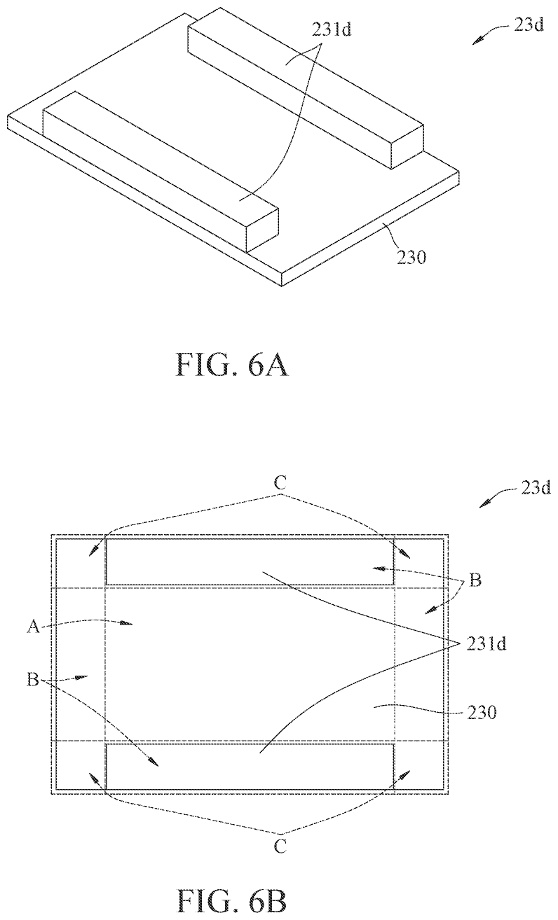

FIG. 6A and FIG. 6B show a heat dissipation structure 23d according to a fourth embodiment of the present disclosure. The same or corresponding members of the heat dissipation structure 23d of the fourth embodiment and the heat dissipation structure 23a of the first embodiment are marked with the same or corresponding numbers, and descriptions of the same parts are omitted.

As shown in FIG. 6A and FIG. 6B, in the fourth embodiment of the present disclosure, the joint member 232 is not provided in the corner area C, and supporting members 231d are disposed in the two opposite edge areas B. In other words, only the two supporting members 231d located in the two edge areas B are supported and connected between the heat dissipation member 230 and the carrier structure 20.

Compared with the first embodiment, the structure of the heat dissipation structure 23d of the fourth embodiment is simpler, so the manufacturing process of the heat dissipation structure 23d can be simplified and the cost can be reduced.

Furthermore, in one embodiment, the supporting members 231d are disposed in the two opposite edge areas B. However, it should be understood that the supporting members 231d only need to be sufficient to support the heat dissipation member 230 in a balanced manner. For example, in other embodiments, the supporting members 231d can be provided in the edge areas B of the adjacent sides.

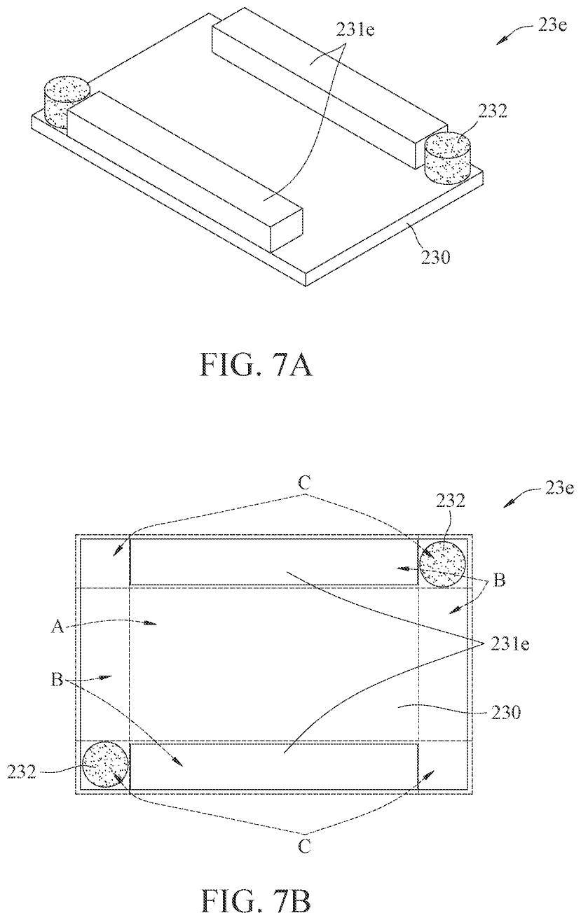

FIG. 7A and FIG. 7B show a heat dissipation structure 23e according to a fifth embodiment of the present disclosure. The same or corresponding members of the heat dissipation structure 23e of the fifth embodiment and the heat dissipation structure 23a of the first embodiment are marked with the same or corresponding numbers, and descriptions of the same parts are omitted.

As shown in FIG. 7A and FIG. 7B, in the fifth embodiment of the present disclosure, joint members 232 are provided in some of the plurality of corner areas C (for example, in two opposite/diagonal corner areas C), and supporting members 231e are provided in some of the plurality of edge areas B (for example, in two opposite edge areas B). It should be understood that the joint members 232 and the supporting members 231e may also be selected to be respectively provided in the three corner areas C and the three edge areas B, and the present disclosure is not limited to the illustration of the fifth embodiment.

In addition, in the foregoing embodiments, the heat dissipation member 230 and the supporting member 231 can be integrally formed. At this time, the supporting member 231 can be disposed along the outer edge of the heat dissipation member 230, so that the cross section of the heat dissipation structure 23 becomes an n-shape (as shown in FIG. 2E and FIG. 2F). However, the present disclosure is not limited to as such, and the integrally formed heat dissipation structure 23 may also be in a non-n-shaped shape.

In addition, in the foregoing embodiments, the heat dissipation member 230 and the supporting member 231 may also be not integrally formed. At this time, the supporting member 231 can be retreated inwardly relative to the outer edge of the heat dissipation member 230 instead of being disposed along the outer edge of the heat dissipation member 230, so that the cross section of the heat dissipation structure 23 becomes π-shaped. However, the present disclosure is not limited to as such, and the non-integrally-formed heat dissipation structure 23 may also be non-π-shaped.

To sum up, in the electronic package and the heat dissipation structure thereof of the present disclosure, the supporting members of the heat dissipation structure are mainly provided in the edge areas, and no supporting members are provided in the corner areas. Thereby, the supporting members located in the edge areas are interrupted at the corner areas and are not connected to each other, so the stress of the supporting members will not be concentrated in the corner areas, thereby preventing the entire electronic package from warping and delamination.

Moreover, the heat dissipation structure of the present disclosure can be provided with the joint member in the corner area, and the joint member can strengthen the connection between the heat dissipation member and the carrier structure, and can also support the heat dissipation member at the same time. Thereby, the stability of the entire electronic package can be further improved to avoid bending deformation.

Furthermore, in the present disclosure, one of the edge areas may be provided with a plurality of supporting members, and the plurality of supporting members are arranged to be spaced apart from each other. In this way, the stress of the supporting member in the edge area can be interrupted, so as to further avoid bending deformation.

Moreover, the supporting members of the present disclosure can also only be arranged in some of the edge areas. Thereby, the structure can be simplified.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A heat dissipation structure, comprising:
a heat dissipation member defined with a central area, a plurality of edge areas located at sides of an outer periphery of the central area, and a plurality of corner areas located at corners of the outer periphery of the central area; and
at least one supporting member disposed on the heat dissipation member;
wherein the supporting member is disposed in the edge area of the heat dissipation member and is not disposed in the corner area.

2. The heat dissipation structure of claim 1, further comprising at least one joint member disposed in the corner area of the heat dissipation member, wherein the joint member and the supporting member are not connected to each other.

3. The heat dissipation structure of claim 2, wherein the joint member is made of soft material, and the supporting member is made of hard material.

4. The heat dissipation structure of claim 2, wherein the joint member is a glue pillar.

5. The heat dissipation structure of claim 1, further comprising a plurality of joint members disposed in some of the plurality of corner areas.

6. The heat dissipation structure of claim 5, wherein the plurality of joint members are disposed in the plurality of corner areas that are opposite.

7. The heat dissipation structure of claim 1, wherein the supporting member is a heat dissipation wall or a heat dissipation pillar.

8. The heat dissipation structure of claim 1, wherein a plurality of the supporting members are disposed in one of the edge areas and spaced apart from each other.

9. The heat dissipation structure of claim 1, wherein the supporting member is disposed in each of two of the edge areas that are opposite.

10. The heat dissipation structure of claim 1, wherein the supporting member is disposed in each of the edge areas.

11. The heat dissipation structure of claim 1, wherein the heat dissipation member and the supporting member are integrally formed.

12. The heat dissipation structure of claim 1, wherein the heat dissipation member and the supporting member are not integrally formed.

13. An electronic package, comprising:
a carrier structure;
an electronic component disposed on the carrier structure; and
a heat dissipation structure disposed on the carrier structure and covering the electronic component, and the heat dissipation structure comprising:
a heat dissipation member defined with a central area, a plurality of edge areas located at sides of an outer periphery of the central area, and a plurality of corner areas located at corners of the outer periphery of the central area; and
at least one supporting member disposed on the heat dissipation member, wherein the heat dissipation structure is disposed on the carrier structure via the supporting member;
wherein the electronic component is corresponding to a position of the central area, and the supporting member is disposed in the edge area of the heat dissipation member but not in the corner area.

14. The electronic package of claim 13, further comprising at least one joint member disposed in the corner area of the heat dissipation member, wherein the joint member and the supporting member are not connected to each other.

15. The electronic package of claim 14, wherein the joint member is made of soft material, and the supporting member is made of hard material.

16. The electronic package of claim 14, wherein the joint member is a glue pillar.

17. The electronic package of claim 13, further comprising a plurality of joint members disposed in some of the plurality of corner areas.

18. The electronic package of claim 17, wherein the plurality of joint members are disposed in the plurality of corner areas that are opposite.

19. The electronic package of claim 13, wherein the supporting member is a heat dissipation wall or a heat dissipation pillar.

20. The electronic package of claim 13, wherein a plurality of the supporting members are disposed in one of the edge areas and spaced apart from each other.

21. The electronic package of claim 13, wherein the supporting member is disposed in each of two of the edge areas that are opposite.

22. The electronic package of claim 13, wherein the supporting member is disposed in each of the edge areas.

23. The electronic package of claim 13, wherein the heat dissipation member and the supporting member are integrally formed.

24. The electronic package of claim 13, wherein the heat dissipation member and the supporting member are not integrally formed.
